(19) United States
(12) Patent Application Publication
(10) Pub. No.: US 2026/0125821 A1
(43) Pub. Date: May 7, 2026

(54) PROCESSING METHOD OF SINGLE-CRYSTAL QUARTZ MATERIAL

(71) Applicant: TXC Corporation, Taipei City (TW)

(72) Inventors: Cheng-Wei Lin, Taipei City (TW); Wun-Kai Wang, Taipei City (TW)

(73) Assignee: TXC Corporation, Taipei City (TW)

(21) Appl. No.: 18/964,713

(22) Filed: Dec. 2, 2024

(30) Foreign Application Priority Data
Nov. 6, 2024 (TW) 113142606

(51) Int. Cl. C30B 29/18; C30B 33/04; C30B 33/08

(52) U.S. Cl. CPC C30B 29/18; C30B 33/04; C30B 33/08

(57) ABSTRACT

A processing method of a single-crystal quartz material includes the following steps. An area to be processed in which the single-crystal quartz material readily generates twin crystals is determined. The area to be processed on the single-crystal quartz material is modified using a modifier, so that a processing difficulty of the area to be processed is reduced. The single-crystal quartz material of the modified area to be processed is processed using a processor.

### CROSS-REFERENCE TO RELATED APPLICATION

This application claims the priority benefit of Taiwan application serial no. 113142606, filed on Nov. 6, 2024. The entirety of the above-mentioned patent application is hereby incorporated by reference herein and made a part of this specification.

### BACKGROUND OF THE INVENTION

### Field Of The Invention

The invention relates to a processing method, and in particular to a processing method of a single-crystal quartz material.

### Description of Related Art

Since an etching process includes a plurality of processes, such as physical vapor deposition (PVD), lithography, and dry/wet etching, compared to using etching to process materials, using laser may reduce the number of manufacturing processes, reduce processing costs, and reduce the load on the etching station, thereby improving production efficiency.

Currently, single-crystal quartz is processed using ultrafast laser, and the laser wavelengths thereof are mostly between UV and IR wavelengths of 355 nm to 1064 nm. The transmittance of quartz for all of these wavelengths is close to 90%, so more energy is needed during processing to induce ablation on the surface of the quartz material, thus leading to excessive heat accumulation. Excessive local temperature or excessive temperature gradient leads to the generation of twin crystals.

### SUMMARY OF THE INVENTION

The invention provides a processing method of a single-crystal quartz material that may effectively prevent the single-crystal quartz material from generating twin crystals after processing.

An embodiment of the invention provides a processing method of a single-crystal quartz material including the following steps. An area to be processed in which the single-crystal quartz material readily generates twin crystals is determined. The area to be processed on the single-crystal quartz material is modified using a modifier, so that a processing difficulty of the area to be processed is reduced. The single-crystal quartz material of the modified area to be processed is processed using a processor.

Based on the above, in an embodiment of the invention, the processing method of the single-crystal quartz material modifies the area to be processed on the single-crystal quartz material using the modifier, so that the processing difficulty of the area to be processed is reduced, and the single-crystal quartz material at the modified area to be processed is processed using the processor. Therefore, modifying the area to be processed first effectively reduces the thermal threshold needed to generate processing effects during processing, and may reduce heat accumulation or thermal effects, thereby reducing processing temperature and temperature gradient. Due to the above effect of reducing processing temperature and temperature gradient, the processing method of the single-crystal quartz material may further avoid the issue of generating twin crystals during processing.

### BRIEF DESCRIPTION OF THE DRAWINGS

FIG. 1 is a flowchart of a processing method of a single-crystal quartz material according to an embodiment of the invention.

FIG. 2 is a schematic diagram of a modifier modifying an area to be processed on a single-crystal quartz material and a processor processing the single-crystal quartz material at the modified area to be processed in a processing method of the single-crystal quartz material according to an embodiment of the invention.

FIG. 3 is a schematic diagram of a processing method of a single-crystal quartz material according to an embodiment of the invention, in which a processor is an etching machine and a hole is formed at the single-crystal quartz material.

FIG. 4 is a detailed flowchart of step S100 in FIG. 1.

FIG. 5 is a detailed flowchart of step S100 in FIG. 1.

FIG. 6 is a detailed flowchart of a processing method of a single-crystal quartz material and step S100 in FIG. 1 according to another embodiment of the invention.

FIG. 7 is a schematic diagram of a specific angle or a specific position of a crystal on a single-crystal quartz material in a processing method of the single-crystal quartz material according to an embodiment of the invention.

### DESCRIPTION OF THE EMBODIMENTS

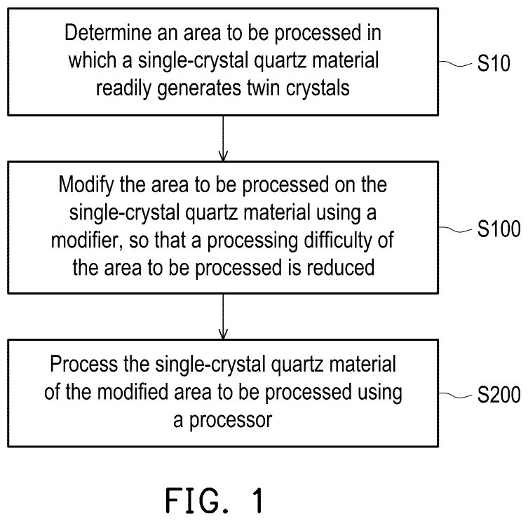

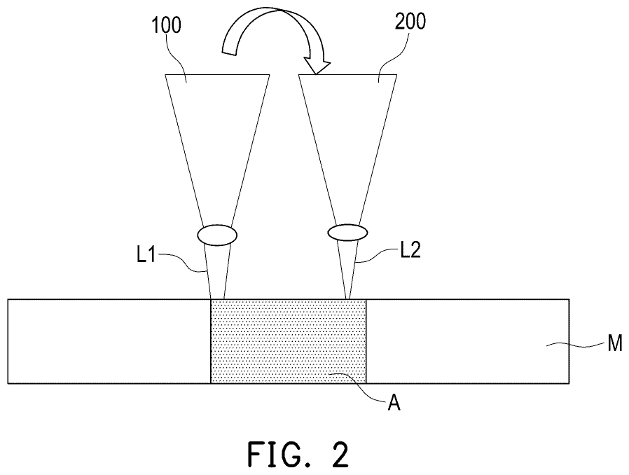

FIG. 1 is a flowchart of a processing method of a single-crystal quartz material according to an embodiment of the invention. FIG. 2 is a schematic diagram of a modifier modifying an area to be processed on a single-crystal quartz material and a processor processing the single-crystal quartz material at the modified area to be processed in a processing method of the single-crystal quartz material according to an embodiment of the invention. Referring to FIG. 1 and FIG. 2, an embodiment of the invention provides a processing method of a single-crystal quartz material M, including the following steps. In step S10, an area A to be processed in which the single-crystal quartz material M readily generates twin crystals is determined. In step S100, the area A to be processed on the single-crystal quartz material M is modified using a modifier 100, so that a processing difficulty of the area A to be processed is reduced. In step S200, the single-crystal quartz material M of the modified area to be processed is processed using a processor 200.

In the present embodiment, when single-crystal quartz (α-SiO2 having temperature T<573 ° C.) is modified, the crystal structure thereof is transformed into amorphous quartz. For this object, the state of single-crystal quartz transforming back into twin crystal quartz (β-SiO2 at 573° C.<T<870° C.) is not included (that is, to avoid becoming β-SiO2 twin crystals). The modifier modifies the area A to be processed, for example, directly or indirectly. The modification method may include the use of a physical or chemical process such as heating, cooling, ion bombardment, and implantation. For example, the modifier 100 may include a heater, a cooler, a plasma machine, an ion bombardment machine, an ion implanter, or a laser, but the invention is not limited thereto. In a preferred embodiment, as shown in FIG. 2, the modifier 100 may be a laser.

In addition, the processing method may include drilling, cutting, or etching, or a combination thereof, but the invention is not limited thereto. For example, the processor 200 may include a plasma machine, an ion bombardment machine, an ion implanter, or a laser. As shown in FIG. 2, the processor 200 may be a laser. The modifier 100 and the processor 200 respectively emit laser light L1 and L2, and heat the area A to be processed via the laser light L1 for modification, and ablate the modified area to be processed via the laser light L2 for processing. In particular, the laser may be selected as picosecond (ps) ultrafast laser or laser having pulse width and unlimited short wavelength (such as parameter 10 ps, wavelength 300 nm, processing energy >0.2 W), such as ultrafast laser having a pulse width less than 1 nanosecond. For example, using layered focus modification, focus depths are spaced at least 5 μm apart. For example, Bessel beam modification: single point vertical modification, the modification range is 5 μm or less at single points and connected. For example, surface modification: focused surface modification for a large area.

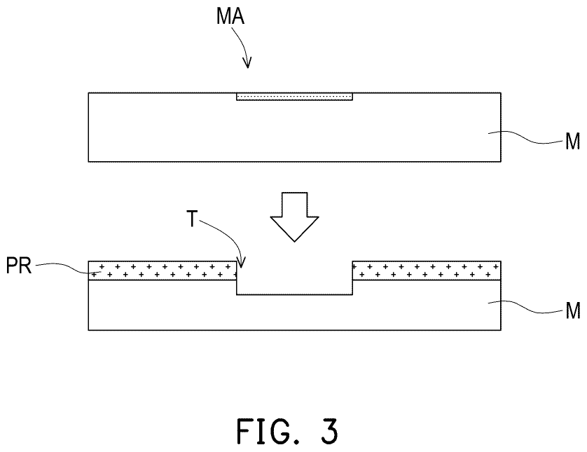

FIG. 3 is a schematic diagram of a processing method of a single-crystal quartz material according to an embodiment of the invention, in which a processor is an etching machine and a hole is formed at the single-crystal quartz material. Referring to FIG. 3, in another embodiment, the processor may include a dry or wet etching machine, and the modified area MA to be processed is processed via an etching process.

For example, modification is performed on the single-crystal quartz material M first, a photoresist layer PR is disposed on the single-crystal quartz material M, the single-crystal quartz material M is exposed using a photomask, and then the single-crystal quartz material M is etched. In particular, for example, a hole T is formed after etching. That is, modifying the area to be processed first before the etching process is performed may speed up the etching process and enhance etching effect. For example, a deeper hole T may be formed. Reducing the processing difficulty described in step S100 is, for example, increasing the etching rate of dry etching/wet etching by at least 200% (depending on etching conditions and parameters), thus reducing the total processing time of the processing method by at least 200%.

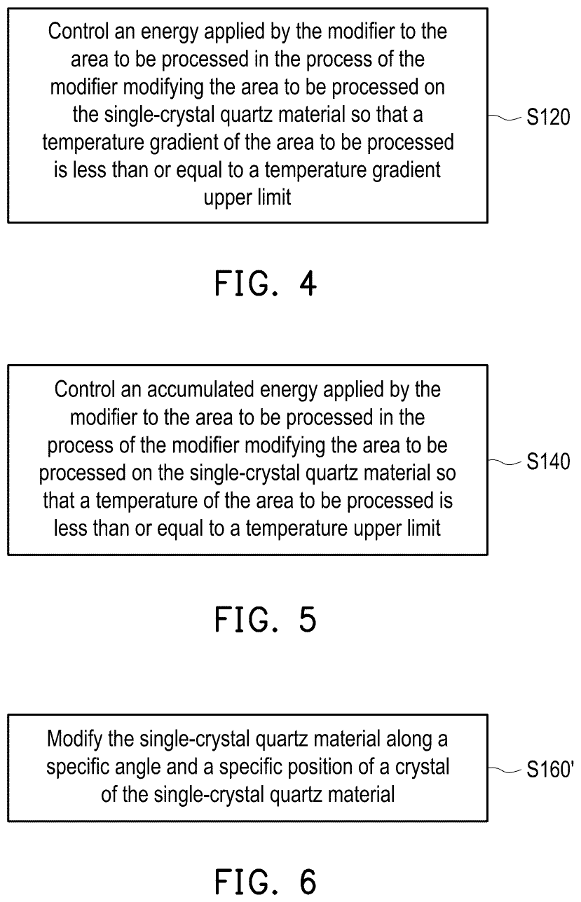

FIG. 4 is a detailed flowchart of step S100 in FIG. 1. Please refer to FIG. 4. In the present embodiment, step S100 includes the following steps. In step S120, an energy applied by the modifier 100 to the area A to be processed is controlled in the process of the modifier 100 modifying the area A to be processed on the single-crystal quartz material M so that the temperature gradient of the area A to be processed is less than or equal to the temperature gradient upper limit

FIG. 5 is a detailed flowchart of step S100 in FIG. 1. Please refer to FIG. 5. In the present embodiment, step S100 further includes the following steps. In step S140, an accumulated energy applied by the modifier 100 to the area A to be processed is controlled in the process of the modifier 100 modifying the area A to be processed on the single-crystal quartz material M so that the temperature of the area A to be processed is less than or equal to the temperature upper limit. In particular, the temperature upper limit is, for example, 573 degrees Celsius.

That is, during the modification process, the instantaneous energy and the accumulated energy applied to the area A to be processed are controlled to avoid the generation of twin crystals to the single-crystal quartz material M during the modification.

FIG. 6 is a detailed flowchart of a processing method of a single-crystal quartz material and step S100 in FIG. 1 according to another embodiment of the invention. Please refer to FIG. 6. In another embodiment, step S100 further includes the following steps. In step S160′, the single-crystal quartz material M is modified along a specific angle and a specific position of a crystal of the single-crystal quartz material M. That is, during the modification process, specific angles and specific positions at which twin crystals are readily generated are modified preferentially to further avoid the generation of twin crystals during the processing.

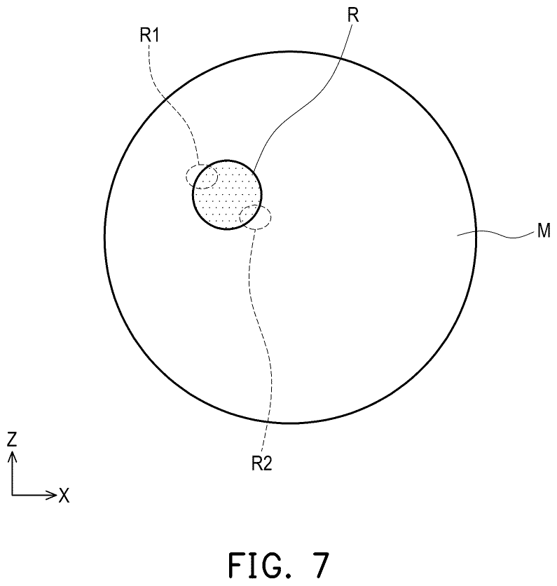

FIG. 7 is a schematic diagram of a specific angle or a specific position of a crystal on a single-crystal quartz material in a processing method of the single-crystal quartz material according to an embodiment of the invention. Taking FIG. 7 as an example, if the single-crystal quartz material M is cut by AT cutting, on the X-Z plane of the single-crystal quartz material M, there is a first twin crystal region R1 at which twin crystals are readily generated at the upper left corner of a region R, and there is a second twin crystal region R2 at which twin crystals are readily generated at 180 degrees corresponding to the first twin crystal region R1. Therefore, in the above step S160′, modification is performed at the first twin crystal region R1 and the second twin crystal region R2 preferentially. However, the invention is not limited to the positions or the angles of the first twin crystal region R1 and the second twin crystal region R2. The specific angles and the specific positions of the crystals on the single-crystal quartz material M should be determined according to the characteristics of the single-crystal quartz material M during processing.

Based on the above, in an embodiment of the invention, the processing method of the single-crystal quartz material includes the following steps. The area to be processed on the single-crystal quartz material is modified using the modifier, so that the processing difficulty of the area to be processed is reduced. The single-crystal quartz material of the modified area to be processed is processed using the processor. That is, the area after the modifier completes the modification may then be processed, or processing may be subsequently performed at different times or different locations after all of the areas that need to be modified are modified. Therefore, modifying the area to be processed first effectively reduces the thermal threshold needed to generate processing effects during processing, and may reduce heat accumulation or thermal effects, thereby reducing processing temperature and temperature gradient. Due to the above effect of reducing processing temperature and temperature gradient, the processing method of the single-crystal quartz material may further avoid the issue of generating twin crystals during the processing.

What is claimed is:

1. A processing method of a single-crystal quartz material, comprising:
determining an area to be processed in which the single-crystal quartz material readily generates twin crystals;
modifying the area to be processed on the single-crystal quartz material using a modifier, so that a processing difficulty of the area to be processed is reduced; and
processing the single-crystal quartz material of the modified area to be processed using a processor.

2. The processing method of the single-crystal quartz material of claim 1, wherein reducing the processing difficulty comprises increasing an etching rate by at least 200%.

3. The processing method of the single-crystal quartz material of claim 1, wherein the modifier comprises a heater, a cooler, a plasma machine, an ion bombardment machine, an ion implanter, or a laser.

4. The processing method of the single-crystal quartz material of claim 1, wherein the processor comprises a plasma machine, an ion bombardment machine, an ion implanter, or an ultrafast laser having a pulse width less than 1 nanosecond.

5. The processing method of the single-crystal quartz material of claim 1, wherein the processor comprises a dry or wet etching machine.

6. The processing method of the single-crystal quartz material of claim 1, wherein the step of modifying the area to be processed on the single-crystal quartz material using the modifier comprises the following steps:
controlling an energy applied by the modifier to the area to be processed in the process of the modifier modifying the area to be processed on the single-crystal quartz material, so that a temperature gradient of the area to be processed is less than or equal to a temperature gradient upper limit.

7. The processing method of the single-crystal quartz material of claim 1, wherein the step of modifying the area to be processed on the single-crystal quartz material using the modifier comprises the following steps:
controlling an accumulated energy applied by the modifier to the area to be processed in the process of the modifier modifying the area to be processed on the single-crystal quartz material, so that a temperature of the area to be processed is less than or equal to a temperature upper limit.

8. The processing method of the single-crystal quartz material of claim 1, wherein the step of modifying the area to be processed on the single-crystal quartz material using the modifier comprises the following steps:
modifying the single-crystal quartz material along a specific angle and a specific position of a crystal of the single-crystal quartz material.
